(19) United States
(12) Patent Application Publication
(10) Pub. No.: US 2015/0060902 A1
(43) Pub. Date: Mar. 5, 2015

(54) PACKAGE OF LIGHT EMITTING DIODE CHIPS

(71) Applicant: Harvatek Corporation, Hsinchu City (TW)

(72) Inventors: Tsung-Kan CHENG, Taipei City (TW); Chia-Chin CHEN, Miaoli County (TW)

(21) Appl. No.: 14/301,323

(22) Filed: Jun. 10, 2014

(30) Foreign Application Priority Data
Aug. 28, 2013 (TW) 102130864

(51) Int. Cl. H01L 25/075; H01L 33/60; H01L 33/50

(52) U.S. Cl. CPC H01L 25/0753; H01L 33/504; H01L 33/60
USPC 257/89

(57) ABSTRACT

The present invention provides a package of LED chips. The package comprises a transparent plate having a front surface and a rear surface, a plurality of LED chips disposed on the front surface, two opposite front surface reflective walls disposed on the front surface and located at two opposite outsides of the plurality of LED chips, a front surface phosphor gel filling between the two opposite front surface reflective walls, two opposite rear surface reflective walls disposed on the rear surface and a rear surface phosphor gel filling between the two opposite rear surface reflective walls. The present invention realizes the light of the package of LED chips can be extracted from both the front side and the rear side to enhance the light extraction efficiency.

### CROSS-REFERENCE TO RELATED APPLICATIONS

This application claims priority to Taiwanese Application Serial Number 102130864, filed Aug. 28, 2013 which is herein incorporated by reference.

### BACKGROUND

1. Field of Invention

The present invention relates to a package of Light Emitting Diode (LED) chips. More particularly, the present invention relates to a package of a plurality of LED chips of which light can be extracted from both a front side and a rear sideof the package.

2. Description of Related Art

A conventional structure of a package of LED chips is that the LED chips are covered by phosphor gel and the extracted light is white light. The package can be disposed on circuit boards and be applied to various products, such as lamps or backlight modules of the televisions.

The conventional package of LED chips uses interior sides of the housing of the package as reflective surfaces to reflect the light that comes from the LED chips. The reflected light is used to excite more phosphors that are located close to the outside edges of the phosphor gels. The reflective surfaces also reflect the excited light coming from h phosphors, thus increasing the light extraction efficiency.

The package of LED chips includes the package of a single chip, and the package of chips connected to form a circuit. The difference of the product characteristics between the package of chips and the package of a single chip is that lamps made up of the former require simpler structures and manufacturing processes. There is no need for soldering a lot of packages of a single chip individually onto the circuit boards.

FIG. 1 is a diagram illustrating a conventional package of a single chip wherein the package has a reflective wall. The package 100 includes a housing 110. A top part of the housing 110 is served as a reflective wall 111 and an interior side of the housing 110 is served as a reflective surface 112. The reflective surface 112 is generally white. In addition, the package 100 has an LED chip 113 and a phosphor gel 114. The reflective surface 112 can reflect the light that comes from the LED chip 113 toward the lateral sides to excite more phosphors (not shown) which are located close to outside edges of the phosphor gel 114. The reflective surface 112 also reflects the excited light coming from the phosphors, thus increasing the light extraction efficiency.

FIG. 2 is a diagram illustrating a cross-sectional view of the conventional package 100 of a single LED chip in FIG. 1, wherein the package 100 has the reflective wall 111. FIG. 2 is used to expound the function of the reflective surface 112 of the reflective wall 111. As shown in FIG. 2, the reflective surface 112 reflects the reference lights A, B, C, D, and D′, C′, B′, A′ that are from the LED chip 113 toward the lateral sides to excite more phosphors 115 which are located dose to outside edges of the phosphor gel 114. The reflective surface 112 also reflects the excited light coming from the phosphors 115.

FIG. 3 is a diagram illustrating another conventional package 300 of LED chips, wherein the package 300 has a reflective wall 311. The package 300 includes a substrate 310, the reflective wall 311 disposed on the top of the substrate 310, and an interior side of the substrate 310 is served as a reflective surface 312. Generally, the reflective surface 312 is white. In addition, the package 300 has LED chips 313 and a phosphor gel 314. The reflective surface 312 can reflect the light that is from the LED chips 313 toward the lateral sides to excite more phosphors (not shown) which are located close to outside edges of the phosphor gel 314. The reflective surface 312 also reflects the light coming from the phosphors, thus increasing the light extraction efficiency. The function of the reflective wall 311 is the same as the descriptions of FIG. 2.

Furthermore, the aforementioned packages usually have a reflective surface at a die bonding platform which is used for fixing the chip(s) to reflect the light extracted from the rear surfaces of the LED chips to enhance the light extraction efficiency, such as the die bonding platform 116 in FIG. 1 and in FIG. 3. Hence, light of the conventional packages of the LED chips can merely be extracted from the front sides of the packages and enhance the light extraction efficiency of the front sides of the packages. The light is unable to be extracted from the front sides as well as the rear sides of the packages simultaneously and it is unable to enhance the light extraction efficiency of the rear sides of the packages.

### SUMMARY

The present invention provides a package of LED chips. The package includes LED chips fixed on a single surface (a front surface) of a transparent plate and reflective walls and phosphor gels disposed on both the front surface and the e surface of the transparent plate. Therefore, the light extracted from both the front side and the rear side of the package of LED chips to enhance the light extraction efficiency of both the front side and the rear side.

The present invention provides a package of LED chips. The package includes a transparent plate, LED chips, two opposite front surface reflective walls, a front surface phosphor gel, two opposite rear surface reflective walls, and a rear surface phosphor gel. The transparent plate has a front surface and an opposite rear surface opposite to the front surface. The LED chips are disposed on the front surface of the transparent plate. The two opposite front surface reflective walls are d posed on the front surface of the transparent plate and on two opposite outsides of the LED chips. The front surface phosphor gel fills a space between the two opposite front surface reflective walls. The two opposite rear surface reflective walls are disposed on the rear surface of the transparent plate. The rear surface phosphor gel fills a space between the two opposite rear surface reflective walls.

In this way, on the front surface of the transparent plate, vertical lights from the front surfaces of the LED chips would emit upward to excite the phosphors which are located close to a central area of the front surface phosphor gel. The lateral lights would be reflected by the front surface reflective walls on the front surface of the transparent plate to excite more phosphors which are located close to outside edges of the front surface phosphor gel. Besides, the front surface reflective walls also reflect the excited light coming from the phosphors to enhance the light extraction efficiency at the front side of the package of LED chips.

Moreover, on the ear surface of the transparent plate, vertical lights from the rear surfaces of the LED chips would emit downward to excite the phosphors which are located close to a central area of the rear surface phosphor gel. The lateral lights would be reflected by the rear surface reflective walls on the rear surface of the transparent plate to excite more phosphors which are located close to outside edges of the rear sur/”face phosphor gel. Besides, the rear surface reflective walls also reflect the excited light coming from the phosphors, thereby enhancing the light extraction efficiency at the rear side of the package of LED chips. Thus, the light of the package can be extracted from both the front side and the rear side of the package, while both the light extraction efficiency of the front side and the rear side is promoted.

In addition, besides the aforementioned front surface phosphor gel or the rear surface phosphor gel including the yellow phosphors, the front surface phosphor gel and/or the rear urface phosphor gel are allowed to be mixed with a few red phosphors to enhance color rendering index (CRI).

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a diagram illustrating a conventional package of a single hip wherein the package has a reflective wall;

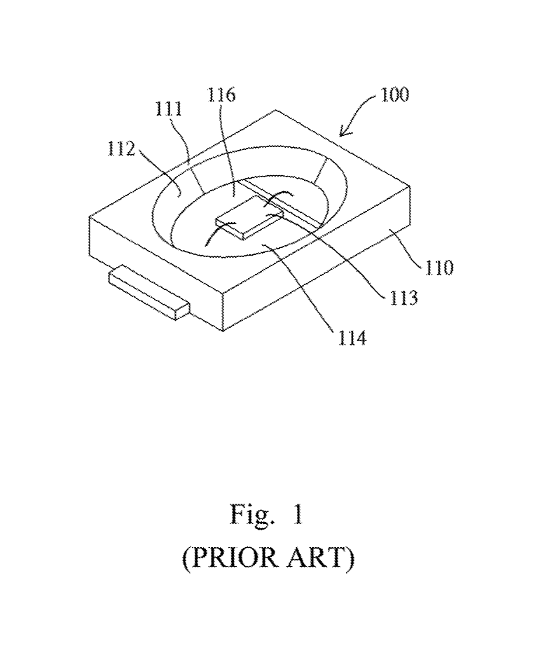

FIG. 2 is a diagram illustrating a cross-sectional view of a conventional package of a single LED chip in FIG. 1, wherein the package has a reflective wall;

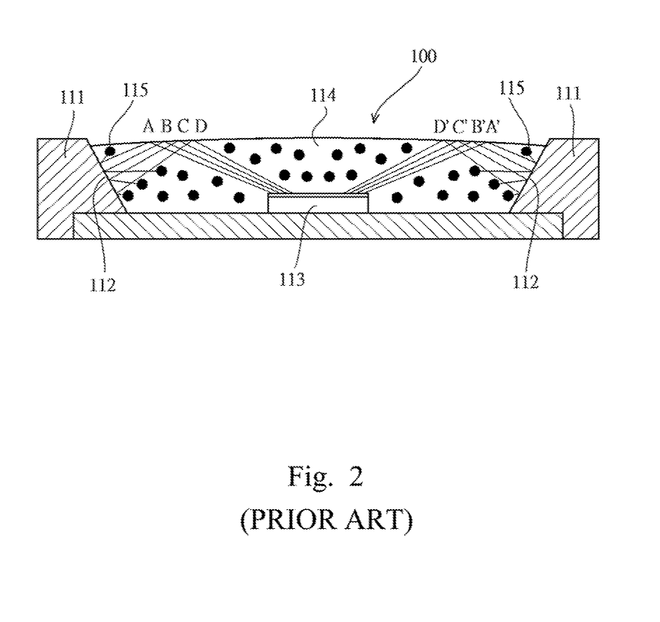

FIG. 3 is a diagram illustrating another conventional package of LED chips, wherein the package has a reflective wall;

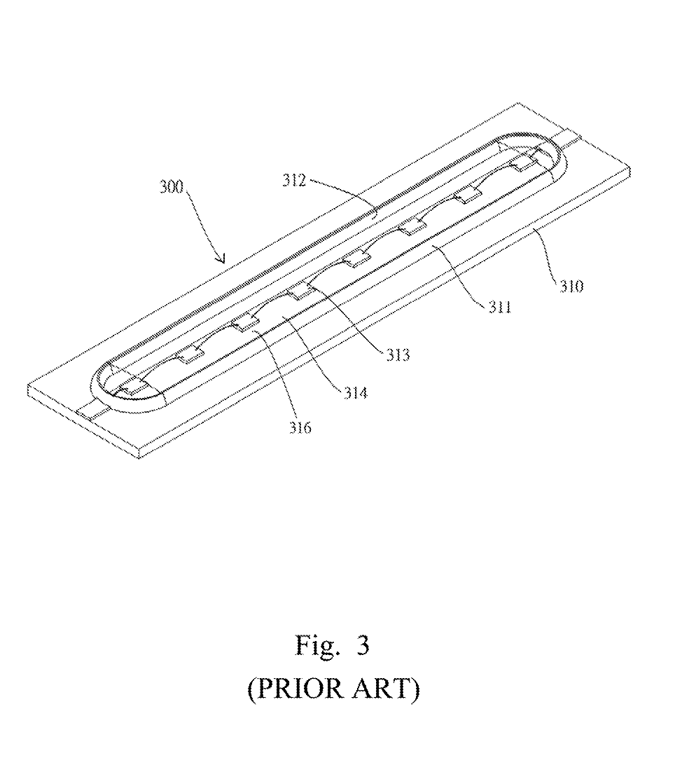

FIG. 4 is a diagram illustrating a package of LED chips according to an exemplary embodiment of the present invention; and

FIG. 5 is a diagram illustrating a cross-sectional view of a package of LED chips in FIG. 4 according to an exemplary embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

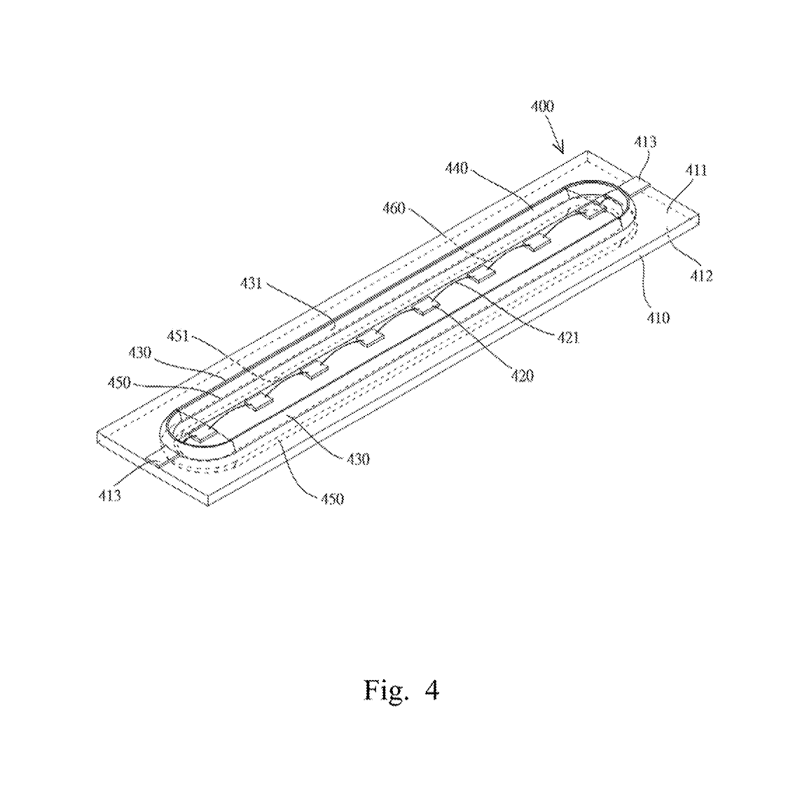

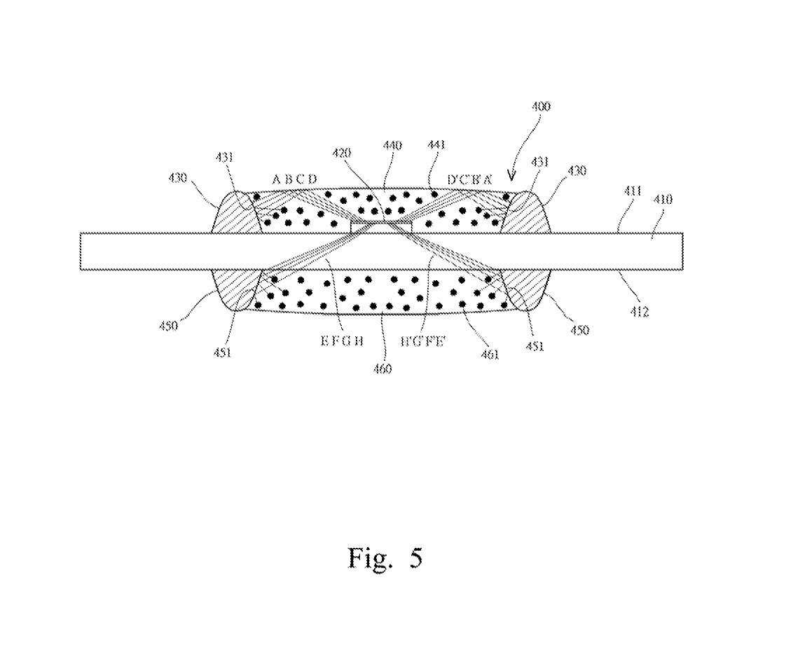

Please refer to FIG. 4 and FIG. 5. According to an exemplary embodiment of the present invention, a package of LED chips 400 includes a transparent plate 410, LED chips 420, two opposite front surface reflective walls 430, a front surface phosphor gel 440, phosphors 441 of the front surface phosphor gel 440, two opposite e surface reflective walls 450, a rear surface phosphor gel 460, and phosphors 461 of the rear surface phosphor gel 460. The package of LED chips 400 can generate white light and so on.

The transparent plate 410 can be a translucent board that is clear or slightly blurry, and can be made of a material such as glass, polymer, resin, or aluminum oxide. The transparent plate 410 has a front surface 411 and a rear surface 412 opposite to the front surface 411.

The LED chips 420 are fixed on the front surface 411 of the transparent plate 410. The LED chips 420 can generate blue light or ultraviolet light. The jumper wires 421 that can be the golden wires, the alloy wires, the copper wires or the aluminum wires are used to connect the positive electrodes and the negative electrodes of the adjacent LED chips 420 to form a series circuit, a parallel circuit, a circuit that the LED chips 420 are connected in series to form series connections and then the series connections are connected in parallel, or a circuit that the LED chips 420 are connected in parallel to form parallel connections and then the parallel connections are connected in series. After that, a positive electrode of the LED chip 420 on a front end of the circuit and a negative electrode of the LED chip 420 on a rear end of the circuit are respectively connected to two end plates 413 fixed on the transparent plate 410. The end plates 413 can be connected to a power source (not shown) to provide the required power for enabling the LED chips 420. In an embodiment, the LED chips 420 are disposed on the end plates 413 by flip chip technology (not shown) to improve the heat dissipation efficiency of the LED chips 420 to increase the package of LED chips 400 reliability. In another embodiment, the wavelength of the light from the LED chips 420 is between 370 nm and 530 nm and the light can excite green phosphors, yellow phosphors or red phosphors to generate lights having different colors to modulate and acquire the required color temperature, such as the warm white light or the cool white light. In another embodiment, the wavelength of the light from the LED chips 420 is between 600 nm and 630 nm and the light can excite blue phosphors to modulate and acquire the required color temperature, such as the warm white light or the cool white light.

The two opposite front surface reflective walls 430 are disposed on the front surface 411 of the transparent plate 410, as shown in FIG. 5. The front surface reflective walls 430 can be disposed on the front surface 411 of the transparent plate 410 and located on the two opposite outsides of the LED chips 420 by a dispenser using silicone liquid. After the curing of the silicone liquid, the two opposite front surface reflective walls 430 would naturally have cross sections of an inverted V shape or an inverted U shape due to the surface tension and the wettability to the transparent plate 410, as shown in FIG. 5; thereby capable of being used as the reflective surface 431. It is not necessary to precisely restrict the distances between one of the two opposite front surface reflective walls 430 and one of the LED chips 420 at the central area because the reflective surfaces 431 always have the reflective effect at any areas as long as the lateral lights from the front surface of the LED chips 420 can reach the reflective surfaces 431 of the front surface reflective walls 430. The reference light travel path is as shown as A, B, C, D, and D′, C′, B′, A′ in FIG. 5. Moreover, a viscosity of the silicone liquid is around 3500 cps (Centipoises). The material of forming the front surface reflective walls 430 is silicone, epoxy, glass or acrylic.

The material of the front surface phosphor gel 440 can be a transparent silicone including phosphors 441. The front surface phosphor gel 440 fills a space between the two opposite front surface reflective walls 430 when the front surface phosphor gel 440 is liquid state and submerges the LED chips 420, and is shaped after the curing. The front surface phosphor gel 440 filling the space between the two opposite front surface reflective walls 430 also has a cross section of V shape or a U shape. The phosphors 441 of the front surface phosphor gel 440 are green phosphors, yellow phosphors, red phosphors, or blue phosphors.

Furthermore, as shown in FIG. 5, the two opposite rear surface reflective wails 450 are disposed on the rear surface 412 of the transparent plate 410. Similar to the process for making the front reflective walls 430, the rear surface reflective walls 450 can be dispensed on the rear surface 412 of the transparent plate 410 by a dispenser using the silicone liquid and located at the positions corresponding to the front surface reflective walls 430 vertically. After the curing of the silicone liquid, the two opposite rear surface reflective walls 450 would naturally have cross sections of a V shape or a U shape due to the surface tension and the wettability to the transparent plate 410, as shown in FIG. 5; thereby capable of being used as the reflective surface 451. It is not necessary to precisely restrict the distance between one of the two opposite rear surface reflective walls 450 and one of the LED chips 420 on the front surface because the reflective surfaces 451 always have the reflective effect at any areas as long as the lateral lights from the rear surface of the LED chips 420 reaches the reflective surfaces 451 of the rear surface reflective walls 450. The reference light travel path is as shown as E, F, G, H and H′, G′, F′, E′ in FIG. 5. Moreover, a viscosity of the silicone liquid is around 3500 cps (Centipoises). The material of forming the rear surface reflective walls 450 is silicone, epoxy, glass or acrylic.

The material of the rear surface phosphor gel 460 can be a transparent silicone including phosphors 461. The rear urface phosphor gel 460 also fills a space between the two opposite rear surface reflective walls 450 when the rear surface phosphor gel 460 is liquid state and submerges a portion of the rear surface 412 of the transparent plate 410 located between the two opposite rear surface reflective walls 450, and is shaped after the curing. The rear surface phosphor gel 460 filling the space between the two opposite rear surface reflective walls 450 also has a cross section of a V shape or a U shape. The phosphors 461 of the rear surface phosphor gel 460 are green phosphors, yellow phosphors, red phosphors, or blue phosphors.

In addition, in order to make the color temperature of the light extracted from the front surface phosphor gel 440 correspond with that of the rear surface phosphor gel 460, the ratio of the phosphors 441 within the front surface phosphor gel 440 and the ratio of the phosphors 461 within the rear surface phosphor gel 460 can be adjusted.

Besides the front surface phosphor gel 440 or the rear surface phosphor gel 460 including the yellow phosphors, the front surface phosphor gel 440 and/or the rear surface phosphor gel 460 are allowed to be mixed with a few little red phosphors to enhance a color rendering index (CRI).

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A package of light emitting diode (LED) chips, comprising:
a transparent plate having a front surface and an opposite rear surface;
a plurality of LED chips disposed on the front surface of the transparent plate;
two opposite front surface reflective walls disposed on the front surface of the transparent plate and located on two opposite outsides of the plurality of LED chips;
a front surface phosphor gel filling a space between the two opposite front surface reflective walls;
two opposite rear surface reflective walls disposed on the rear surface of the transparent plate; and
a rear surface phosphor gel filling a space between the two opposite rear surface reflective walls.

2. The package of light emitting diode (LED) chips of claim 1, wherein the front surface phosphor gel and/or the rear surface phosphor gel comprises phosphors selected from a group consisting of yellow phosphors, red phosphors, green phosphors, and blue phosphors.

3. The package of light emitting diode (LED) chips of claim 1, the LED chips generate blue light or ultraviolet light.

4. The package of light emitting diode (LED) chips of claim 1, the front surface reflective walls or the rear surface reflective all have a cross section of a V shape or a U shape.

5. The package of light emitting diode (LED) chips of claim 1, a material of the transparent plate is selected from a group consisting of glass, polymer, resin, and aluminum oxide.

6. The package of light emitting diode (LED) chips of claim, a color temperature of the light extracted from the front surface phosphor gel corresponds with that of the light extracted from the rear phosphor gel.

7. The package of light emitting diode (LED) chips of claim 1, a ratio of phosphors within the front phosphor gel is different from that of phosphors within the rear phosphor gel.

8. The package of light emitting diode (LED) chips of claim the front surface phosphor gel or the rear surface phosphor gel has a cross section of a V shape or a U shape.

9. The package of light emitting diode (LED) chips of claim 1, a material of the front surface reflective walls or the e surface reflective walls is selected from a group consisting of silicon dioxide, epoxy, glass, and acrylic.

10. The package of light emitting diode (LED) chips of claim 1, the front surface phosphor gel submerges the plurality of LED chips.

11. The package of light emitting diode (LED) chips of claim 1, further comprising an end plate on the transparent plate, wherein the plurality of LED chips are disposed on the end plate by flip chip technology.

12. The package of light emitting diode (LED) chips of claim 1, wherein the front surface phosphor gel or the rear surface phosphor gel comprises silicone.

13. The package of light emitting diode (LED) chips of claim 1, wherein the front surface reflective walls or he rear surface reflective walls comprise a reflective surface.

14. The package of light emitting diode (LED) chips of claim 1, wherein the rear surface reflective walls are located at positions corresponding to the front surface reflective walls vertically.
